(19) United States
(12) Patent Application Publication
(10) Pub. No.: US 2026/0247591 A1
(43) Pub. Date: Aug. 20, 2026

(54) DEVICE COMPRISING A SHIELD LAYER COMPRISING A PLURALITY OF OPENINGS FILLED WITH A THERMAL INTERFACE MATERIAL

(71) Applicant: QUALCOMM Incorporated, San Diego, CA (US)

(72) Inventors: Yan CAO, Shanghai (CN); Hui HE, Changsha (CN); Wei TANG, Shanghai (CN); Feihu YE, Shanghai (CN)

(21) Appl. No.: 19/161,529

(22) PCT Filed: Mar. 20, 2023
(86) PCT No.: PCT/CN2023/082407

§ 371 Date: Sep. 2, 2025

(51) Int. Cl. H05K 9/00; H05K 7/20

(52) U.S. Cl. CPC H05K 9/0022; H05K 7/2039; H05K 9/0088

(57) ABSTRACT

A device comprising a board, an integrated device coupled to the board, a shield frame coupled to the board, a shield layer coupled to the shield frame, wherein the shield layer comprises a first surface, a second surface and a plurality of openings, a thermal interface material coupled to (i) the integrated device and (ii) the shield layer. The thermal interface material is located in the plurality of openings of the shield layer. The thermal interface material touches the integrated device, the first surface of the shield layer and the second surface of the shield layer.

### FIELD

Various features relate to a device that includes a shield and a thermal interface material.

### BACKGROUND

Electronic devices include many components that generate heat, such as integrated devices. Integrated devices may be prone to overheating, which can affect the performance of the integrated devices and other components of the electronic device. An integrated device that is overheating has a high junction temperature, which can result in high surface temperature for the electronic device. This may ultimately affect the performance of the electronic device. There is an ongoing need to improve the heat dissipating performance of an electronic device that includes a component that generates heat. For example, there is an ongoing need to reduce the junction temperature of components that generate heat and/or reduce the surface temperature of an electronic device that includes components that generate heat.

### SUMMARY

Various features relate to a device that includes a shield and a thermal interface material.

One example provides a device comprising a board, an integrated device coupled to the board, a shield frame coupled to the board, a shield layer coupled to the shield frame, wherein the shield layer comprises a first surface, a second surface and a plurality of openings, a thermal interface material coupled to (i) the integrated device and (ii) the shield layer. The thermal interface material is located in the plurality of openings of the shield layer. The thermal interface material touches the integrated device, the first surface of the shield layer and the second surface of the shield layer.

Another example provides a method that provides a first shield layer comprising a first surface and a second surface. The method forms a first plurality of openings in the first shield layer. The method couples a first thermal interface material to the first shield layer such that the first thermal interface material is located in the first plurality of openings of the first shield layer touching (i) the first surface of the first shield layer and (ii) the second surface of the first shield layer. The method couples the first shield layer to a shield frame, such that the first plurality of openings are located over an integrated device, and where the first thermal interface material is coupled to the integrated device.

### BRIEF DESCRIPTION OF THE DRAWINGS

Various features, nature and advantages may become apparent from the detailed description set forth below when taken in conjunction with the drawings in which like reference characters identify correspondingly throughout.

FIG. 1 illustrates an exemplary front side view of an electronic device that includes a display.

FIG. 2 illustrates an exemplary back side view of an electronic device that includes an integrated device.

FIG. 3 illustrates an exemplary cross sectional profile view of a device that includes a an integrated device and a shield metal layer comprising a plurality of openings filled with a thermally interface material.

FIG. 4 illustrates an exemplary cross sectional profile view of a shield metal layer comprising a plurality of openings filled with a thermally interface material.

FIG. 5 illustrates an exemplary plan view of a shield metal layer comprising a plurality of openings.

FIG. 6 illustrates an exemplary plan view of a shield metal layer comprising a plurality of openings filled with a thermally interface material.

FIG. 7 illustrates an exemplary view of an assembly that includes a shield metal layer comprising a plurality of openings filled with a thermally interface material.

FIG. 8 illustrates an exemplary view of an assembly that includes a shield metal layer comprising a plurality of openings filled with a thermally interface material.

FIG. 9 illustrates an exemplary graph of junction temperatures over time for different shield metal layers.

FIG. 10 illustrates an exemplary junction temperature map for device with an integrated device coupled to a shield metal layer w/o a plurality of holes.

FIG. 11 illustrates an exemplary junction temperature map for device with an integrated device coupled to a shield metal layer that includes a plurality of holes.

FIG. 12 illustrates an example of a shield metal layer with a plurality of openings in an arrangement.

FIG. 13 illustrates an example of another shield metal layer with a plurality of openings in another arrangement.

FIG. 14 illustrates an example of another shield metal layer with a plurality of openings in yet another arrangement.

FIG. 15 illustrates an exemplary graph of shielding effectiveness for various configurations of a shield metal layer.

FIG. 16 illustrates an exemplary graph of shielding effectiveness for various configurations of a shield metal layer.

FIG. 17 illustrates an exemplary graph of shielding effectiveness for various configurations of a shield metal layer.

FIG. 18 illustrates an exemplary sequence for fabricating shield metal layer comprising a plurality of openings filled with a thermal interface material.

FIG. 19 illustrates an exemplary sequence for fabricating shield metal layer comprising a plurality of openings filled with a thermal interface material.

FIG. 20 illustrates an exemplary sequence for fabricating shield metal layer comprising a plurality of openings filled with a thermal interface material.

FIG. 21 illustrates an exemplary flow diagram of a method for providing an assembly comprising an integrated device and a shield metal layer comprising a plurality of openings filled with a thermal interface material.

FIG. 22 illustrates various electronic devices that may integrate a die, an integrated device, an integrated passive device (IPD), a passive component, a package, and/or a device package described herein.

### DETAILED DESCRIPTION

In the following description, specific details are given to provide a thorough understanding of the various aspects of the disclosure. However, it will be understood by one of ordinary skill in the art that the aspects may be practiced without these specific details. For example, circuits may be shown in block diagrams in order to avoid obscuring the aspects in unnecessary detail. In other instances, well-known circuits, structures and techniques may not be shown in detail in order not to obscure the aspects of the disclosure.

The present disclosure describes a device (e.g., electronic device) that comprises a board, an integrated device coupled to the board, a shield frame coupled to the board, a shield metal layer coupled to the shield frame, a thermal interface material coupled to (i) the integrated device and (ii) the shield metal layer. The shield metal layer comprises a first surface, a second surface and a plurality of openings. The thermal interface material is located in the plurality of openings of the shield metal layer. The thermal interface material touches the integrated device, the first surface of the shield metal layer and the second surface of the shield metal layer. The device may include a frame (e.g., mid-frame). The thermal interface material may be coupled to and touching the frame. The frame may include a heat sink and/or a heat pipe. As will be further described below, the use of a shield metal layer that includes a plurality of openings (e.g., plurality of holes) and a thermal interface material that is (i) located at least in the plurality of openings of the shield metal layer and (ii) coupled to and touching the integrated device and the frame, helps provide a device with effective heat dissipation and effective shielding (e.g., electromagnetic interference shielding), which helps improve and optimize the performance of the integrated device and/or the device.

### Exemplary Device Comprising a Shield Metal Layer Comprising a Plurality of Openings Filled With a Thermal Interface Material.

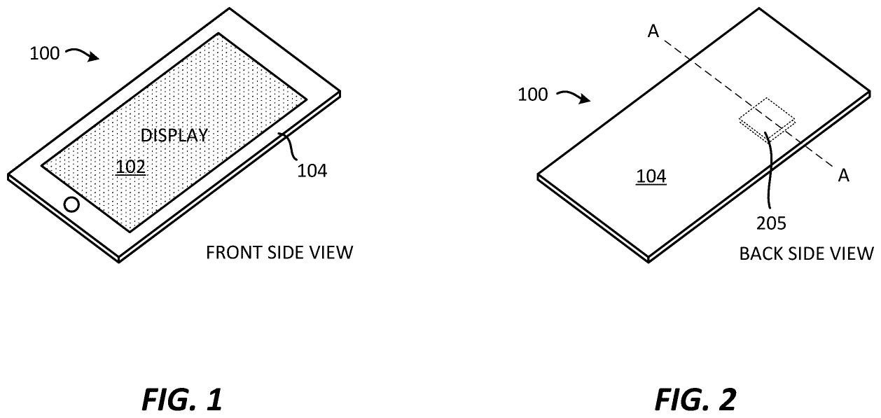

FIGS. 1 and 2 illustrate a device 100 that may include a shield layer with a plurality of openings. The device 100 may include an electronic device, such as a mobile phone (e.g., smart phone). FIG. 1 illustrates an exemplary front side view of a device 100 that includes a display 102 and a casing body 104. FIG. 2 illustrates an exemplary back side view of the device 100. The device 100 includes an integrated device 205. The device 100 may include other integrated devices (not shown). The integrated device 205 may be a first integrated device. The integrated device 205 is located inside the device 100. For example, the integrated device 205 is located inside the casing body 104. The integrated device 205 may include a System-on-Chip (SoC).

As will be further described below, the device 100 also includes a shield layer (e.g., shield metal layer, flexible metal foil) that includes a plurality of openings (e.g., plurality of holes) and a thermal interface material located in the plurality of openings of the shield layer and touching the integrated device 205 and a frame in the device 100.

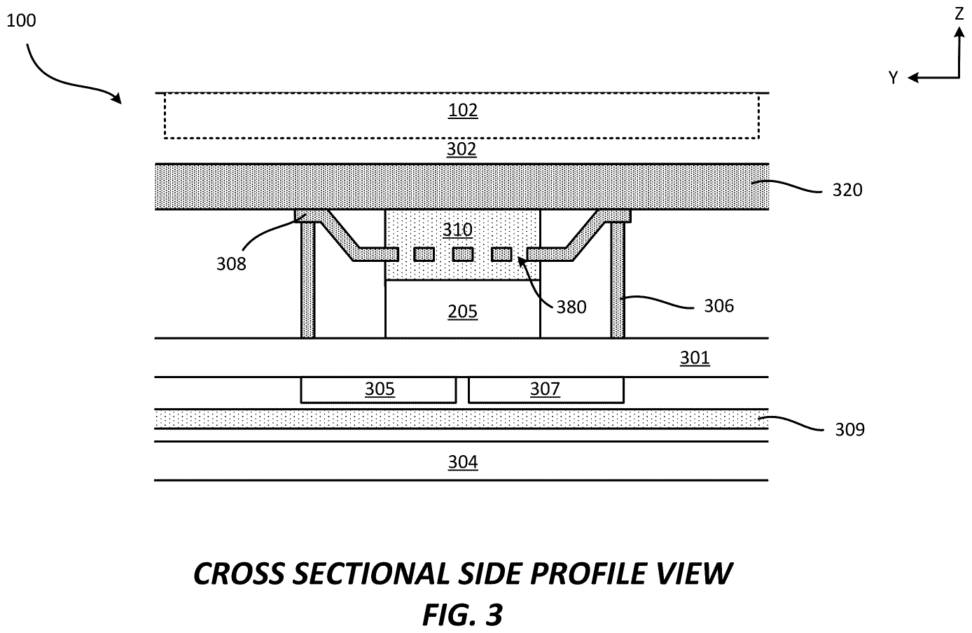

FIG. 3 illustrates an exemplary cross sectional profile view of the cross section AA of the device 100 of FIG. 2. The device 100 includes the display 102, a display module 302, a frame 320, a back cover 304, an antenna frame 309, a board 301, an integrated device 205, an integrated device 305, an integrated device 307, a shield frame 306, a shield metal layer 308 and a thermal interface material 310. The shield metal layer 308 may be a type of a shield layer (e.g., electromagnetic interference shield layer).

The integrated device 205 is coupled to a first surface of the board 301. The integrated device 205 may be coupled to the board 301 through a plurality of solder interconnects (not shown). In some implementations, there may be a package substrate (not shown) or an interposer (not shown) between the integrated device 205 and the board 301. In such instances, the integrated device 205 may be coupled to a package substrate (or an interposer) through a first plurality of solder interconnects, and the package substrate (or the interposer) may be coupled to the board 301 through a second plurality of solder interconnects. The integrated device 305 and the integrated device 307 are coupled to a second surface of the board 301. A plurality of solder interconnects may be used to couple the integrated device 305 and the integrated device 307 to the board 301. The second surface of the board 301 is opposite to the first surface of the board 301. The board 301 may be a printed circuit board (PCB). The antenna frame 309 is located between the board 301 and the back cover 304. The antenna frame 309 may be located between the integrated device 305 and the back cover 304. The antenna frame 309 may be located between the integrated device 307 and the back cover 304.

The shield frame 306 is coupled to the first surface of the board 301. The shield frame 306 may laterally surround the integrated device 205. The shield frame 306 may include a metal material. Different implementations may use different materials for the shield frame 306. The shield metal layer 308 is coupled to the shield frame 306. An adhesive may be used to couple the shield metal layer 308 to the shield frame 306. The shield metal layer 308 may be located over (e.g., above) the integrated device 205 and the board 301. The shield metal layer 308 and the shield frame 306 may surround and/or encapsulate the integrated device 205. The shield frame 306 and/or the shield metal layer 308 may form a compartment around the integrated device 205. The shield metal layer 308 includes a plurality of openings 380. One or more openings from the plurality of openings 380 may include one or more holes. One or more openings from the plurality of openings 380 may have the same and/or similar sizes and/or shapes. However, in some implementations, one or more openings from the plurality of openings 380 may have different sizes and/or shapes. The plurality of openings 380 may be located over (e.g., above) the integrated device 205. The shield metal layer 308 may include a flexible metal layer. The shield metal layer 308 may include several metal layers (e.g., laminated metal layers). The shield metal layer 308 may include a metal foil (e.g., flexible metal foil). In some implementations, the shield metal layer 308 may include a plurality of metal foils (e.g., plurality of flexible metal foils). The shield metal layer 308 may have different thicknesses. The shield frame 306 and/or the shield metal layer 308 may be configured as an electromagnetic interference (EMI) shield for the integrated device 205.

As mentioned above, the shield metal layer 308 includes a plurality of openings 380. The thermal interface material 310 is located in the plurality of openings 380. The thermal interface material 310 is coupled to the shield metal layer 308, the integrated device 205 and the frame 320. The thermal interface material 310 may fill the plurality of openings 380 of the shield metal layer 308. The thermal interface material 310 may also be located above and below the shield metal layer 308. For example, the thermal interface material 310 may be coupled to a first surface and a second surface of the shield metal layer 308. The thermal interface material 310 may be coupled to the back side of the integrated device 205 and the frame 320.

At least part of the thermal interface material 310 may include a continuous and/or contiguous material between the integrated device 205 and the frame 320. Having at least part of a thermal interface material that is continuous and/or contiguous between the integrated device 205 and the frame 320 helps provide improved heat dissipation since there is less and/or reduced thermal contact resistance due to the presence of the plurality of openings 380 of the shield metal layer 308. Thermal contact resistance is a phenomenon in which heat flow and/or heat transfer is impeded at the contact interface of two different materials. For example, since two materials that are in contact with each other may not be perfectly flat at the microscopic level, there may be air and/or gas that may be located and/or trapped between the two materials that are in contact with each other. Since air and/or gas is a relatively poor conductor of heat, heat transfer between two materials may have some thermal contact resistance, which reduces the overall effectiveness of the heat transfer.

For example, in the event there is no opening in the shield metal layer 308, there would be thermal contact resistance between (i) a thermal interface material below the shield metal layer 308 and the second surface (e.g., bottom surface) of the shield metal layer 308, and (ii) the first surface (e.g., top surface) of the shield metal layer 308 and the thermal interface material above the shield metal layer 308. However, the presence of the plurality of openings 380 reduces the above thermal contact resistance of the heat flow and/or heat transfer by reducing the size of the contact interference between the thermal interface material 310 and the shield metal layer 308. The number of openings and the size of the openings in the shield metal layer 308 will affect and/or determine how much the thermal contact resistance is reduced. Reducing the thermal contact resistance means that the thermal interface material 310 is more effective at providing heat transfer, which means that less thermal interface material 310 may be required to provide effective heat dissipation for the integrated device 205. The use of less thermal interface material 310 may be mean a thinner thermal interface material 310 between the integrated device 205 and the frame 320, which means that the device 100 may be smaller and/or thinner. As will be further described above, the use of a plurality of openings 380 helps provide effective shielding for the integrated device 205. In some implementations, one or more openings of the plurality of openings 380 may have a diameter and/or width of about 2 millimeters or less.

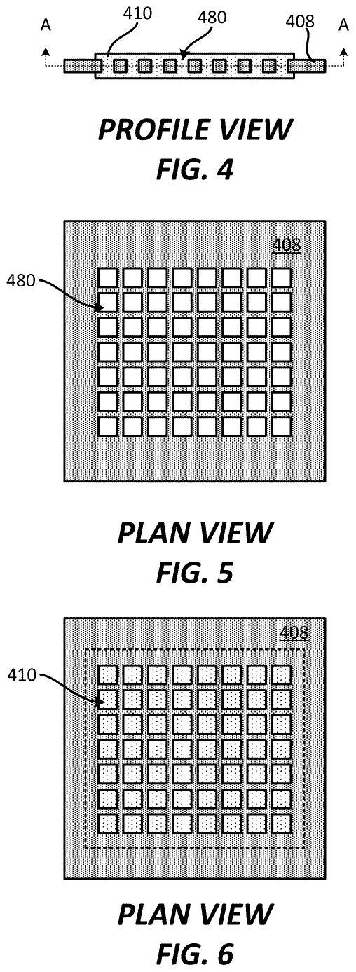

FIGS. 4-6 illustrate exemplary views of a shield metal layer and a thermal interface material. FIG. 4 illustrates a cross sectional profile view of a shield metal layer 408 and a thermal interface material 410. The shield metal layer 408 includes a plurality of openings 480. The thermal interface material 410 is located in the plurality of openings 480. The thermal interface material 410 is also located above the first surface of the shield metal layer 408 and below the second surface of the shield metal layer 408. The shield metal layer 408 may include one or more metal foils. (e.g., flexible foil layers). FIG. 5 illustrates a plan view of the shield metal layer 408 and the plurality of openings 480. FIG. 5 illustrates that the plurality of openings 480 are arranged in a 7×8 array. Each of the openings from the plurality of openings 480 have a square shape. However, one or more openings from the plurality of openings 480 may have different shapes and/or sizes. Moreover, the plurality of openings 480 may be arranged in a different sized array. FIG. 6 illustrates the thermal interface material 410 located in the plurality of openings 480 and above a first surface of the shield metal layer 408. Although not visible in FIG. 6, the thermal interface material 410 may also be located below a second surface of the shield metal layer 408. The shield metal layer 408 may be an example of any of the shield layer(s) and/or shield metal layer(s) described in the disclosure.

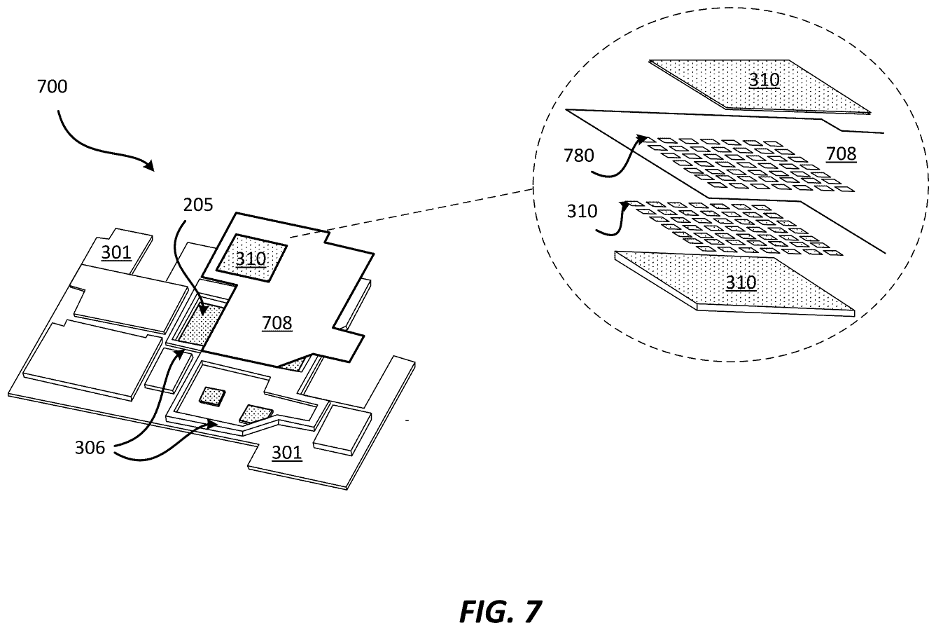

FIG. 7 illustrates an assembly 700 that includes a board 301, an integrated device 205, a shield frame 306, a shield metal layer 708 and a thermal interface material 310. The assembly 700 may be implemented in the device 100. The integrated device 205 is coupled to a first surface of the board 301 (e.g., through a plurality of solder interconnects, which is not shown). In some implementations, the integrated device 205 may be a System on Chip (Soc). The shield frame 306 is coupled to the first surface of the board 301 and may laterally surround the integrated device 205. The shield frame 306 may laterally surround other components coupled to the board 301. The shield metal layer 708 may include a plurality of openings 780. The plurality of openings 780 may be located over the integrated device 205. The shield metal layer 708 may be coupled to the shield frame 306. In some implementations, the shield metal layer 708 is coupled to the shield frame 306 through an adhesive. The thermal interface material 310 is located in the plurality of openings 780. The thermal interface material 310 is coupled to and touching the integrated device (e.g., a back side of the integrated device). The thermal interface material 310 may also be coupled to and touching a frame (e.g., 320, not shown in FIG. 7), a heat sink (not shown) and/or a heat pipe (e.g., not shown). In some implementations, a heat sink and/or a heat pipe may be considered part of a frame (e.g., mid frame).

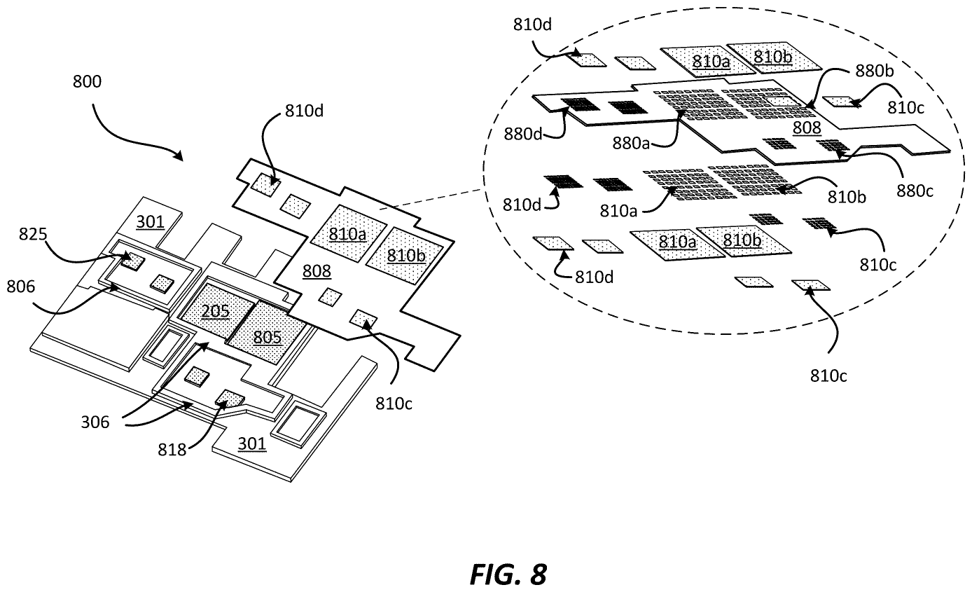

FIG. 8 illustrates an assembly 800 that includes a board 301, an integrated device 205, an integrated device 805, an integrated device 818, an integrated device 825, a shield frame 306, a shield frame 806, a shield metal layer 808 and a thermal interface material 810. The assembly 800 may be implemented in the device 100.

The integrated device 205 is coupled to a first surface of the board 301 (e.g., through a plurality of solder interconnects, which is not shown). The integrated device 805 is coupled to the first surface of the board 301 (e.g., through a plurality of solder interconnects, which is not shown). The integrated device 818 is coupled to the first surface of the board 301 (e.g., through a plurality of solder interconnects, which is not shown). The integrated device 825 is coupled to the first surface of the board 301 (e.g., through a plurality of solder interconnects, which is not shown).

The shield frame 306 is coupled to the first surface of the board 301 and may laterally surround the integrated device 205, the integrated device 805 and the integrated device 818. The integrated device 205 and the integrated device 805 may be located in a first compartment of the shield frame 306. The integrated device 818 may be located in a second compartment of the shield frame 306. The shield frame 806 is coupled to the first surface of the board 301 and may laterally surround the integrated device 825. The integrated device 825 may be located in a compartment of the shield frame 806. In some implementations, the integrated device 205, the integrated device 805, the integrated device 818 and/or the integrated device 825 may be a chiplet. For example, the integrated device 205 may be a first chiplet, the integrated device 805 may be a second chiplet, the integrated device 818 may be a third chiplet and the integrated device 825 may be a fourth chiplet. Each of the chiplets may be configured to be electrically coupled to one another through the board 301.

In some implementations, one of more of integrated devices (e.g., 205, 805, 818, 825) described in the disclosure may be fabricated using the same technology node or two or more different technology nodes. For example, an integrated device (e.g., 205) may include a first chiplet that may be fabricated using a first technology node, and another integrated device (e.g., 805, 818, 825) may include a second chiplet that may be fabricated using a second technology node that is not as advanced as the first technology node. In such an example, the integrated device (e.g., 205) may include components (e.g., interconnects, transistors) that have a first minimum size, and the other chiplet (e.g., 805, 818, 825) may include components (e.g., interconnects, transistors) that have a second minimum size, where the second minimum size is greater than the first minimum size. In some implementations, the integrated device 205 and the integrated device 805 of a package, may be fabricated using the same technology node or different technology nodes. In some implementations, a chiplet (e.g., 818) and another chiplet (e.g., 825) of a package, may be fabricated using the same technology node or different technology nodes.

The shield metal layer 808 may be configured to be coupled to the shield frame 306 and the shield frame 806. The shield metal layer 808 may be configured to be coupled to the shield frame 306 and the shield frame 806 through a respective adhesive. The shield metal layer 808 may include a plurality of openings 880. The plurality of openings 880 may include a first plurality of openings 880a, a second plurality of openings 880b, a third plurality of openings 880c and a fourth plurality of openings 880d. The thermal interface material 810 may include a first thermal interface material 810a, a second thermal interface material 810b, a third thermal interface material 810c and a fourth thermal interface material 810d.

The first plurality of openings 880a are located over the integrated device 205. The second plurality of openings 880b are located over the integrated device 805. The third plurality of openings 880c are located over the integrated device 818. The fourth plurality of openings 880d are located over the integrated device 825.

The first thermal interface material 810a is located in the first plurality of openings 880a and coupled to and touching the integrated device 205. The second thermal interface material 810b is located in the second plurality of openings 880b and coupled to and touching the integrated device 805. The third thermal interface material 810c is located in the third plurality of openings 880a and coupled to and touching the integrated device 818. The fourth thermal interface material 810d is located in the fourth plurality of openings 880d and coupled to and touching the integrated device 825.

The thermal interface material 810 (including the first thermal interface material 810a, the second thermal interface material 810b, the third thermal interface material 810c, and the fourth thermal interface material 810d) may also be coupled to and touching a frame (e.g., 320, not shown in FIG. 8), a heat sink (not shown) and/or a heat pipe (e.g., not shown). In some implementations, a heat sink and/or a heat pipe may be considered part of a frame (e.g., mid frame).

FIG. 8 illustrates that the number, the size, the shape and/or the arrangement (e.g., array size) of the plurality of openings 880 for the shield metal layer 808 may be different. For example, the first plurality of openings 880a may be have a different number of openings from the third plurality of openings 880c. In some implementations, one or more openings from the plurality of openings 880a may have a diameter and/or width for an opening that is different than the diameter and/or width for an opening from the plurality of openings 880c. FIG. 8 illustrates that the shield metal layer 808 is coupled to two shield frames (e.g., 306, 806). In some implementations, the shield metal layer 808 may be broken up into two or more separate shield metal layers. Thus, for example a first shield metal layer could be coupled to the shield frame 306 and a second shield metal layer could be coupled to the shield frame 806.

Different implementations may use different materials for a shield metal layer (e.g., 308, 408, 708, 808) and/or different materials for a thermal interface material (e.g., 310, 410) described in the disclosure. For example, the thermal interface material 310 may include a silicone compound. The thermal interface material may include a thermal grease, a thermal gel, a thermal putty, a thermal pad, and/or a thermal tape. The thermal interface material may include a phase change material, a thermally conductive adhesive, a liquid metal, graphene and/or carbon fiber. In some implementations, the thermal interface material may have a thermal conductivity value (K) of at least 2 W/(m k) (e.g., 13 W/(m k). A shield metal layer may include copper foil, graphite, aluminum foil, aerogel, and/or a copper composite. The shield metal layer may include gold, silver, copper, iron, tin, zinc, lead, nickel, aluminum, tungsten, molybdenum, tantalum, niobium, titanium and steel and/or stainless steel. The shield metal layer may include graphite/graphene, fullerene, carbon fiber, CNT (carbon nano tube), adamas, carbon aerogel, carbon and metal nanocomposites. The shield metal layer may include conductive polymers and composites. In some implementations, the shield metal layer may include two or more metal layers of different materials. A shield metal layer may be a type of a shield layer. A shield layer may include a shield metal layer. A shield metal layer as used in the disclosure may be implemented as a shield layer that does not include a metal material. A shield layer and/or shield metal layer may include any combinations of the above materials and/or any of the above materials in combination with other materials. In some implementations, the shield metal layer may have a thermal conductivity value (K) of about 400 W/(m k). In some implementations, a shield layer and/or a shield metal layer may have a thickness of about 0.05 millimeter (mm) or higher.

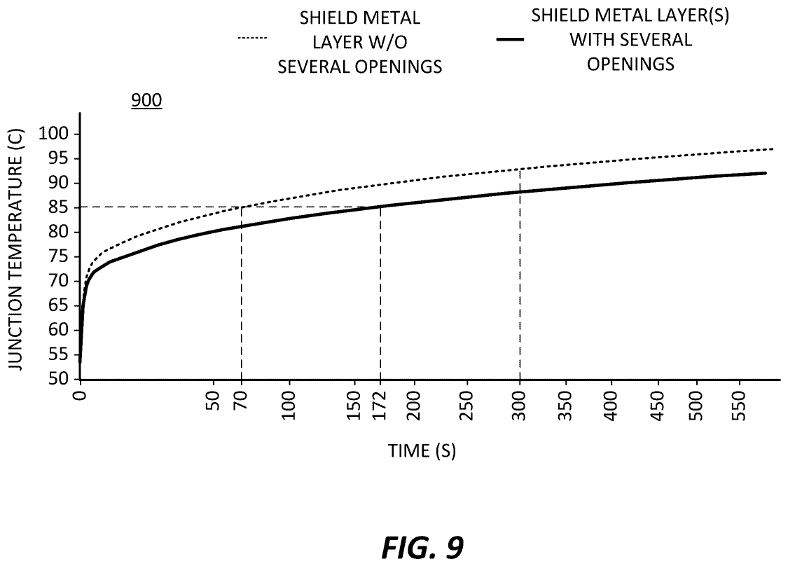

FIG. 9 illustrates a graph 900 that shows the junction temperature over time of (i) an integrated device with a shield metal layer with several openings and a thermal interface material and (ii) an integrated device with a shield metal layer w/o several openings and a thermal interface material. The graph 900 illustrates that an integrated device with a shield metal layer w/o several openings takes about 70 seconds to reach a junction temperature of 85 degrees Celsius. Moreover, after about 300 seconds of operation, the junction temperature is about 92.6 degrees Celsius. However, for an integrated device with a shield metal layer with several openings, it takes about 172 seconds to reach a junction temperature of 85 degrees Celsius. After about 300 seconds of operation, the junction temperature is about 87.9 degrees Celsius. Thus, the graph 900 of FIG. 9 illustrates the performance advantage of a shield metal layer with a plurality of openings (e.g., plurality of holes). It is noted that different configurations of the shield metal layer with different openings may produce different temperature profiles over time. As such, the graph 900 is merely one example of how a shield metal layer with several openings may help with the thermal performance of an integrated device.

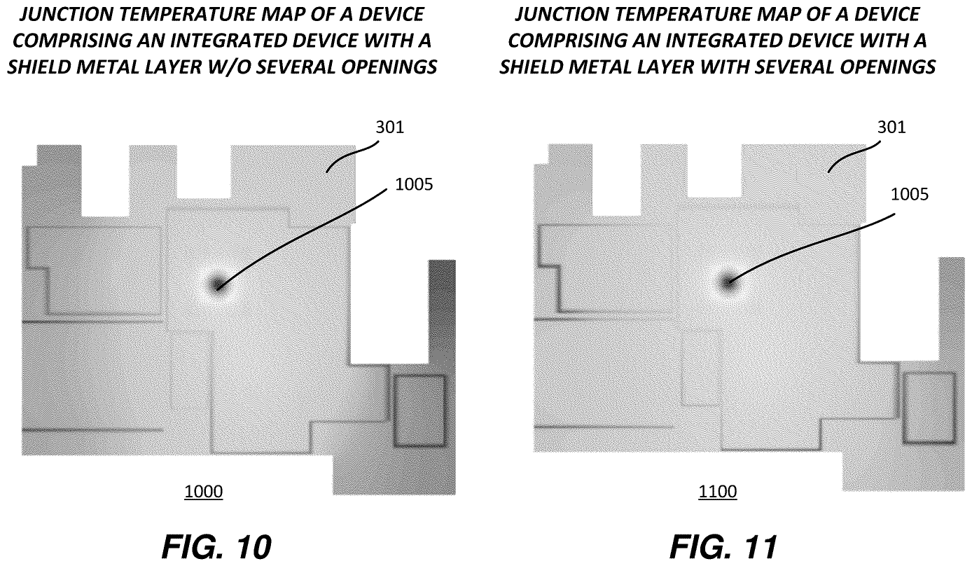

FIGS. 10 and 11 illustrate exemplary temperature maps and/or heat maps that show temperatures at junction points of components configured to generate heat. FIG. 10 illustrates an example of a junction temperature map 1000 for a device that includes an integrated device with a shield metal layer without several openings and a thermal interface material. The junction temperature map 1000 includes a junction temperature at the integrated device 205, which is reflected by the location 1005 on the junction temperature map 1000. The location 1005 is shown overlayed over the board 301. When a device that includes an integrated device with a shield metal layer without several openings is in operation, the temperature at the location 1005 may reach 102 degrees Celsius.

FIG. 11 illustrates an example of a junction temperature map 1100 for a device that includes an integrated device with a shield metal layer with several openings and a thermal interface material. The junction temperature map 1100 includes a junction temperature at the integrated device 205, which is reflected by the location 1005 on the junction temperature map 1100. The location 1005 is shown overlayed over the board 301. When a device that includes an integrated device with a shield metal layer with several openings is in operation, the temperature at the location 1005 may reach 97 degrees Celsius.

Thus, as shown in FIGS. 10 and 11, the use of a shield metal layer with several openings helps decrease the junction temperature of the integrated device, which helps prevent the integrated devices from overheating. This can lead to better performance of the integrated device and/or the device that include the integrated device. It is noted that different configurations of the shield metal layer with different openings may produce different temperature maps. As such, the junction temperature map 1100 is merely one example of how a shield metal layer with several openings may help with the performance of an integrated device and/or a device.

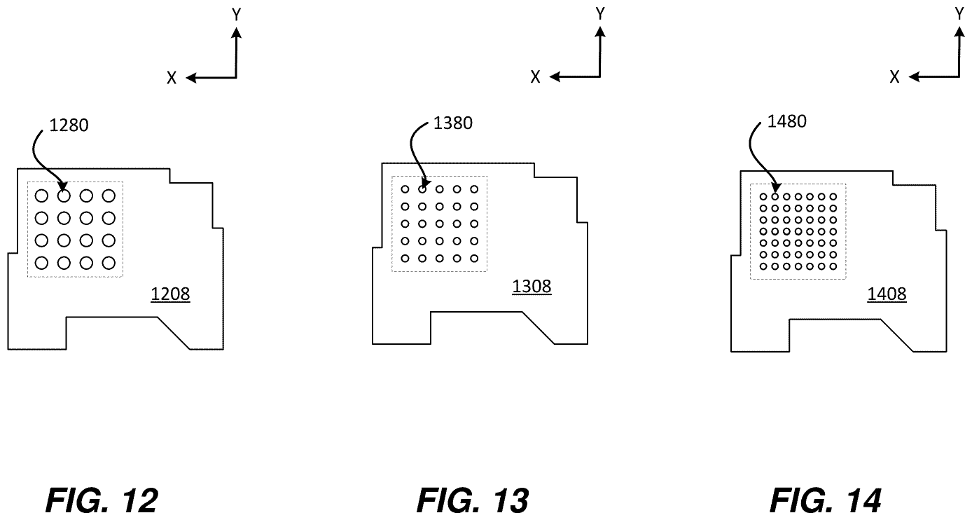

FIGS. 12-14 illustrate various examples of configurations of openings in a shield metal layer. FIG. 12 illustrates a shield metal layer 1208 that includes a plurality of openings 1280 (e.g., holes) arranged in a 4×4 array. Each opening from the plurality of openings 1280 may have a diameter of about 2 millimeters. The plurality of openings 1280 may be positioned over an integrated device.

FIG. 13 illustrates a shield metal layer 1308 that includes a plurality of openings 1380 (e.g., holes) arranged in a 5×5 array. Each opening from the plurality of openings 1380 may have a diameter of about 1.5 millimeters. The plurality of openings 1380 may be positioned over an integrated device.

FIG. 14 illustrates a shield metal layer 1408 that includes a plurality of openings 1480 (e.g., holes) arranged in a 7×7 array. Each opening from the plurality of openings 1480 may have a diameter of about 1 millimeter. The plurality of openings 1480 may be positioned over an integrated device.

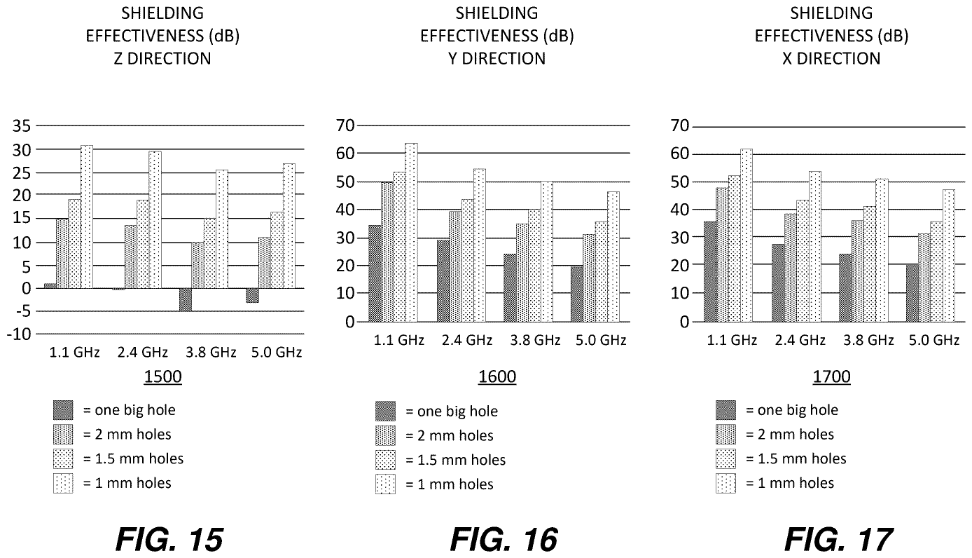

FIGS. 15-17 illustrate examples of shielding effectiveness of various configurations of a plurality of openings in a shield metal layer. FIG. 15 illustrates an example of shielding effectiveness for various frequencies along the Z direction for (i) a shield metal layer with only one big opening, (ii) the shield metal layer 1208 of FIG. 12, (iii) the shield metal layer 1308 of FIG. 13, and (iv) the shield metal layer 1408 of FIG. 14. FIG. 16 illustrates an example of shielding effectiveness for various frequencies along the X direction for (i) a shield metal layer with only one big opening, (ii) the shield metal layer 1208 of FIG. 12, (iii) the shield metal layer 1308 of FIG. 13, and (iv) the shield metal layer 1408 of FIG. 14. FIG. 17 illustrates an example of shielding effectiveness for various frequencies along the Y direction for (i) a shield metal layer with only one big opening, (ii) the shield metal layer 1208 of FIG. 12, (iii) the shield metal layer 1308 of FIG. 13, and (iv) the shield metal layer 1408 of FIG. 14.

As shown in FIGS. 15-17, a shield metal layer with several openings provides better shielding than a shield metal layer with one big opening. FIGS. 15-17 also illustrates that using a shield metal layer with more openings with smaller diameters and/or widths is better at providing shielding (e.g., electromagnetic interference shielding) than using larger sized openings.

An integrated device (e.g., 205) may include a die (e.g., semiconductor bare die). The integrated device may include a power management integrated circuit (PMIC). The integrated device may include an application processor. The integrated device may include a modem. The integrated device may include a radio frequency (RF) device, a passive device, a filter, a capacitor, an inductor, an antenna, a transmitter, a receiver, a gallium arsenide (GaAs) based integrated device, a surface acoustic wave (SAW) filter, a bulk acoustic wave (BAW) filter, a light emitting diode (LED) integrated device, a silicon (Si) based integrated device, a silicon carbide (SiC) based integrated device, a memory, power management processor, and/or combinations thereof. An integrated device (e.g., 205, 805, 818, 825) may include at least one electronic circuit (e.g., first electronic circuit, second electronic circuit, etc . . . ) . An integrated device may include transistors. An integrated device may be an example of an electrical component and/or electrical device. In some implementations, an integrated device may be a chiplet. A chiplet may be fabricated using one or more fabrication processes that provide better yield compared to a fabrication process used on another type of integrated device, which can lower the overall cost of fabricating a chiplet. Different chiplets may have different sizes and/or shapes. Different chiplets may be configured to provide different functions. Different chiplets may have different interconnect densities (e.g., interconnects with different width and/or spacing). In some implementations, several chiplets may be used to perform the functionalities of one or more chips (e.g., one more integrated devices). Using several chiplets that perform several functions may reduce the overall cost of a package relative to using a single chip to perform all of the functions of a package.

In some implementations, one or more of the chiplets and/or one of more of integrated devices (e.g., 205, 805, 818, 825) described in the disclosure may be fabricated using the same technology node or two or more different technology nodes. For example, an integrated device (e.g., 205) may be fabricated using a first technology node, and another chiplet (e.g., 805, 818, 825) may be fabricated using a second technology node that is not as advanced as the first technology node. In such an example, the integrated device (e.g., 205) may include components (e.g., interconnects, transistors) that have a first minimum size, and the chiplet may include components (e.g., interconnects, transistors) that have a second minimum size, where the second minimum size is greater than the first minimum size. In some implementations, the integrated device 205 and the integrated device 805 of a package, may be fabricated using the same technology node or different technology nodes. In some implementations, a chiplet and another chiplet of a package, may be fabricated using the same technology node or different technology nodes.

One or more of the integrated devices may be implemented in a radio frequency (RF) package. The RF package may be a radio frequency front end (RFFE) package. A package may be configured to provide Wireless Fidelity (WiFi) communication and/or cellular communication (e.g., 2G, 3G, 4G, 5G). The packages may be configured to support Global System for Mobile (GSM) Communications, Universal Mobile Telecommunications System (UMTS), and/or Long-Term Evolution (LTE). The packages may be configured to transmit and receive signals having different frequencies and/or communication protocols.

### Exemplary Sequence for Fabricating a Shield Metal Layer With Several Openings Filled With a Thermal Interface Material

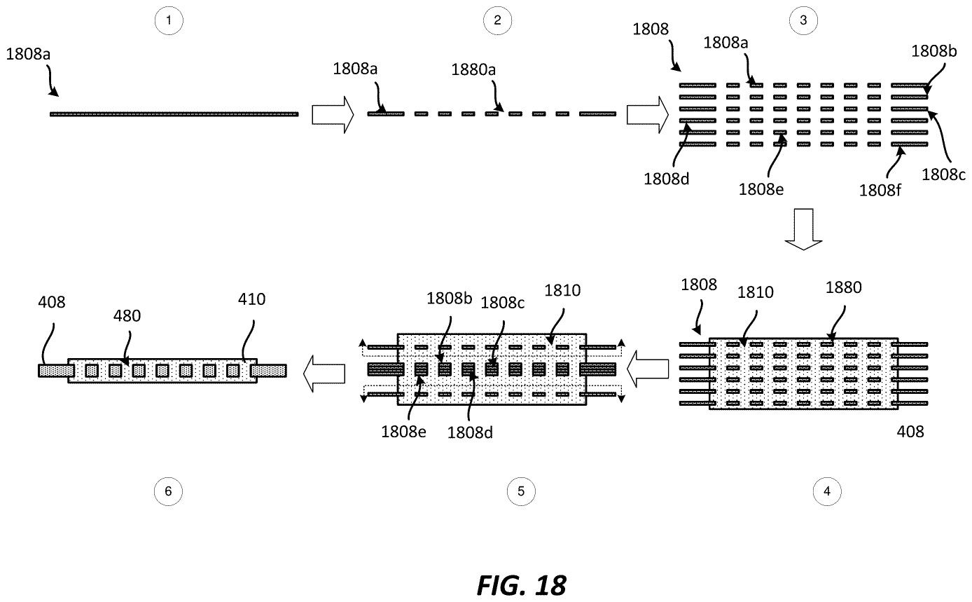

FIG. 18 illustrates an exemplary sequence for providing or fabricating a shield metal layer with a plurality of openings and a thermal interface material. In some implementations, the sequence of FIG. 18 may be used to provide or fabricate the shield metal layer 408 and the thermal interface material 410. However, the sequence of FIG. 18 may be used to fabricate any of the shield metal layers and/or shield layers described in the disclosure.

It should be noted that the sequence of FIG. 18 may combine one or more stages in order to simplify and/or clarify the sequence for providing or fabricating a shield metal layer and a thermal conductive material. In some implementations, the order of the processes may be changed or modified. In some implementations, one or more of processes may be replaced or substituted without departing from the spirit of the disclosure.
Stage 1, as shown in FIG. 18, illustrates a state after a metal layer 1808a is provided. The metal layer 1808a may have different shapes. Different implementations may use different materials for the metal layer 1808a.
Stage 2 illustrates a state after a plurality of openings 1880a are formed in in the metal layer 1808a. A laser drilling process may be used to form the plurality of openings 1880a. However, different implementations may use different processes for forming the plurality of openings 1880a. The plurality of openings 1880a may have different number of openings. Each opening may have the same or similar sizes and/or shapes. However, in some implementations, one or more openings may have different sizes and/or shapes. The plurality of openings 1880a may be have different arrangements such as different array sizes.
Stage 3 illustrates a state after a plurality of metal layers 1808 are provided, where each metal layer includes a plurality of openings. In this example, the plurality of metal layers 1808 includes a metal layer 1808a, a metal layer 1808b, a metal layer 1808c, a metal layer 1808d, a metal layer 1808e and a metal layer 1808f. The plurality of metal layers 1808 may be stacked metal layers. The metal layers of the plurality of metal layers 1808 may all be the same material or may include different material. For example, a first metal layer may include a first material, a second metal layer may include a second material and a third metal layer may include a third material.
Stage 4 illustrates a state after a thermal interface material 1810 is provided and coupled to the plurality of metal layers 1808. The thermal interface material may be provided in the plurality of openings 1880 of the plurality of metal layers 1808. The plurality of metal layers 1808 and the thermal interface material 1810 may be pressed and/or compressed. Different implementations may use different materials for the thermal interface material 1810.
Stage 5 illustrates how the metal layer 1808b, the metal layer 1808c, the metal layer 1808d and the metal layer 1808e from the plurality of metal layers 1808 can be cut together with a thermal interface material 1810.
Stage 6 illustrates a shield metal layer 408 that includes the plurality of openings 480 and the thermal interface material 410. The shield metal layer 408 may be formed from the metal layer 1808b, the metal layer 1808c, the metal layer 1808d and the metal layer 1808e. The thermal interface material 410 may be from the thermal interface material 1810.

### Exemplary Sequence for Fabricating a Shield Metal Layer With Several Openings Filled With a Thermal Interface Material

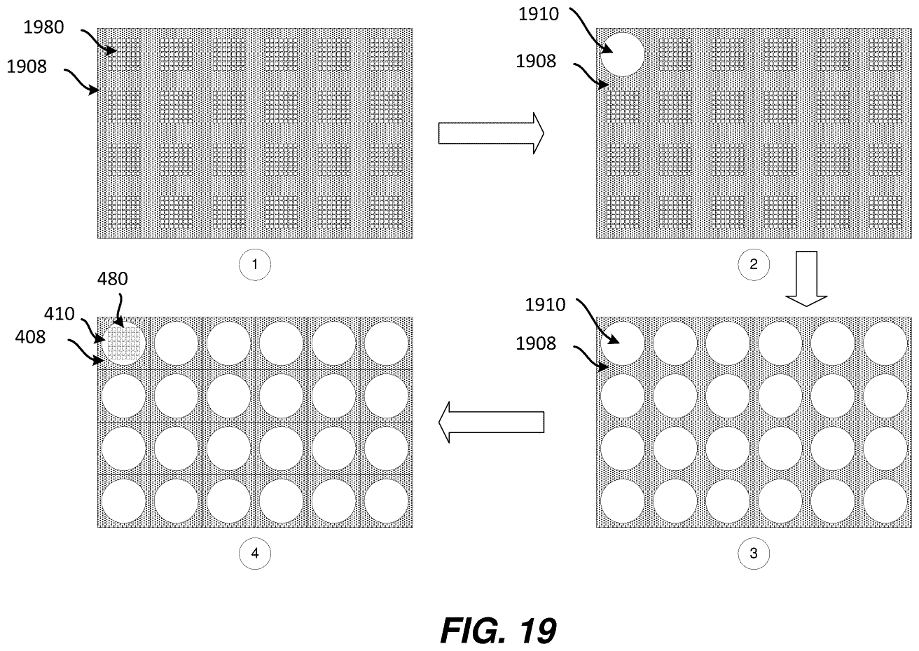

FIG. 19 illustrates an exemplary sequence for providing or fabricating a shield metal layer with a plurality of openings and a thermal interface material. In some implementations, the sequence of FIG. 19 may be used to provide or fabricate the shield metal layer 408 and the thermal interface material 410. However, the sequence of FIG. 19 may be used to fabricate any of the shield metal layers and/or shield layers described in the disclosure.

It should be noted that the sequence of FIG. 19 may combine one or more stages in order to simplify and/or clarify the sequence for providing or fabricating a shield metal layer and a thermal conductive material. In some implementations, the order of the processes may be changed or modified. In some implementations, one or more of processes may be replaced or substituted without departing from the spirit of the disclosure.
Stage 1, as shown in FIG. 19, illustrates a state after a metal layer 1908 is provided. Different implementations may use different materials for the metal layer 1908. The metal layer 1908 includes a plurality of openings 1980. A laser drilling process may be used to form the plurality of openings 1980. However, different implementations may use different processes for forming the plurality of openings 1980. The plurality of openings 1980 may have different number of openings. Each opening may have the same or similar sizes and/or shapes. However, in some implementations, one or more openings may have different sizes and/or shapes. The plurality of openings 1980 may be have different arrangements such as different array sizes. The plurality of openings 1980 may be from several groups of plurality of openings.
Stage 2 illustrates a state after a thermal interface material 1910 is provided and coupled to the metal layer 1908. The thermal interface material may be provided in the plurality of openings 1980 of the metal layer 1908. The thermal interface material 1910 may be injected in the plurality of openings 1980. Different implementations may use different materials for the thermal interface material 1910. The thermal interface material 1910 is thicker than the thickness of the metal layer 1908. Some of the thermal interface material 1910 is located below the metal layer 1908, some of the thermal interface material 1910 is located in the plurality of openings 1980 of the metal layer 1908, and some of the thermal interface material 1910 is located above the metal layer 1908.
Stage 3 illustrates a state after the thermal interface material 1910 is provided and coupled to other plurality of openings of the metal layer 1908, in a similar manner as described at stage 2 of FIG. 19.
Stage 4 illustrates a state after the metal layer 1908 is cut to form individual shield metal layers (e.g., shield metal layer 408) that each includes the plurality of openings 480 and the thermal interface material 410.

### Exemplary Sequence for Fabricating a Shield Metal Layer With Several Openings Filled With a Thermal Interface Material

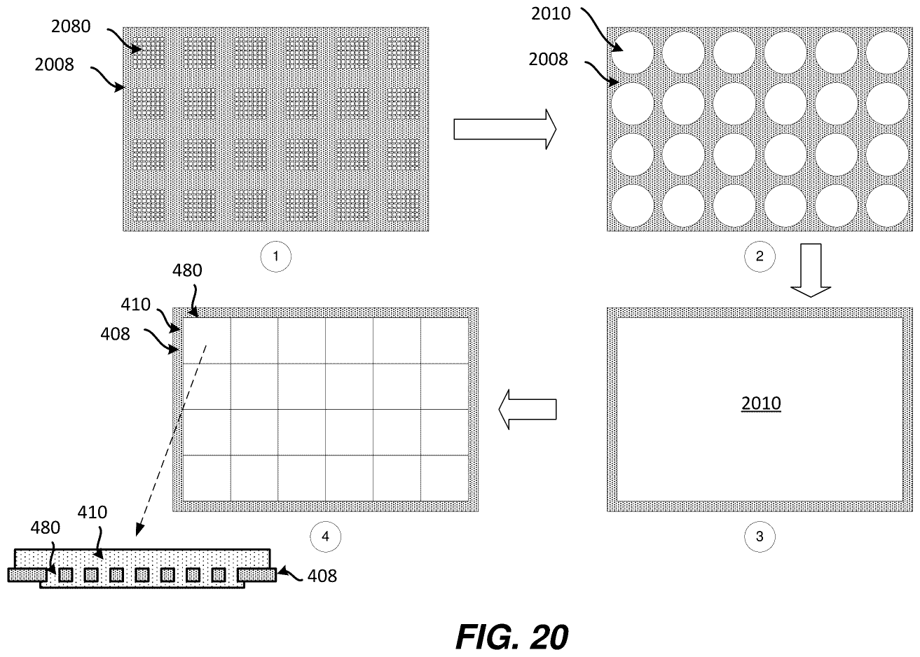

FIG. 20 illustrates an exemplary sequence for providing or fabricating a shield metal layer with a plurality of openings and a thermal interface material. In some implementations, the sequence of FIG. 20 may be used to provide or fabricate the shield metal layer 408 and the thermal interface material 410. However, the sequence of FIG. 20 may be used to fabricate any of the shield metal layers and/or shield layers described in the disclosure.

It should be noted that the sequence of FIG. 20 may combine one or more stages in order to simplify and/or clarify the sequence for providing or fabricating a shield metal layer and a thermal conductive material. In some implementations, the order of the processes may be changed or modified. In some implementations, one or more of processes may be replaced or substituted without departing from the spirit of the disclosure.
Stage 1, as shown in FIG. 20, illustrates a state after a metal layer 2008 is provided. Different implementations may use different materials for the metal layer 2008. The metal layer 2008 includes a plurality of openings 2080. A laser drilling process may be used to form the plurality of openings 2080. However, different implementations may use different processes for forming the plurality of openings 2080. The plurality of openings 2080 may have different number of openings. Each opening may have the same or similar sizes and/or shapes. However, in some implementations, one or more openings may have different sizes and/or shapes. The plurality of openings 2080 may be have different arrangements such as different array sizes. The plurality of openings 2080 may be from several groups of plurality of openings.
Stage 2 illustrates a state after a thermal interface material 2010 is provided and coupled to the metal layer 2008. The thermal interface material may be provided in the plurality of openings 2080 and other openings from a group of plurality of openings. The thermal interface material 2010 may be injected in the plurality of openings 2080. Different implementations may use different materials for the thermal interface material 2010.
Stage 3 illustrates a state after the thermal interface material 2010 is further provided and coupled to the metal layer 2008, such that a footprint of the thermal interface material 2010 is greater on one side of the metal layer 2008 than it is for a footprint of the thermal interface material 2010 on a another side of the metal layer 2008.
Stage 4 illustrates a state after the metal layer 2008 is cut to form individual shield metal layer 408 that includes the plurality of openings 480 and the thermal interface material 410. Stage 4 illustrates that a footprint of the thermal interface material 410 is greater on one side (e.g., first side, top side) of the shield metal layer 408 than it is for a footprint of the thermal interface material 410 on a another side (e.g., second side, bottom side) of the shield metal layer 408.

### Exemplary Flow Diagram of a Method for Providing an Assembly Comprising an Integrated Device and a Shield Metal Layer With Several Openings Filled With a Thermal Interface Material

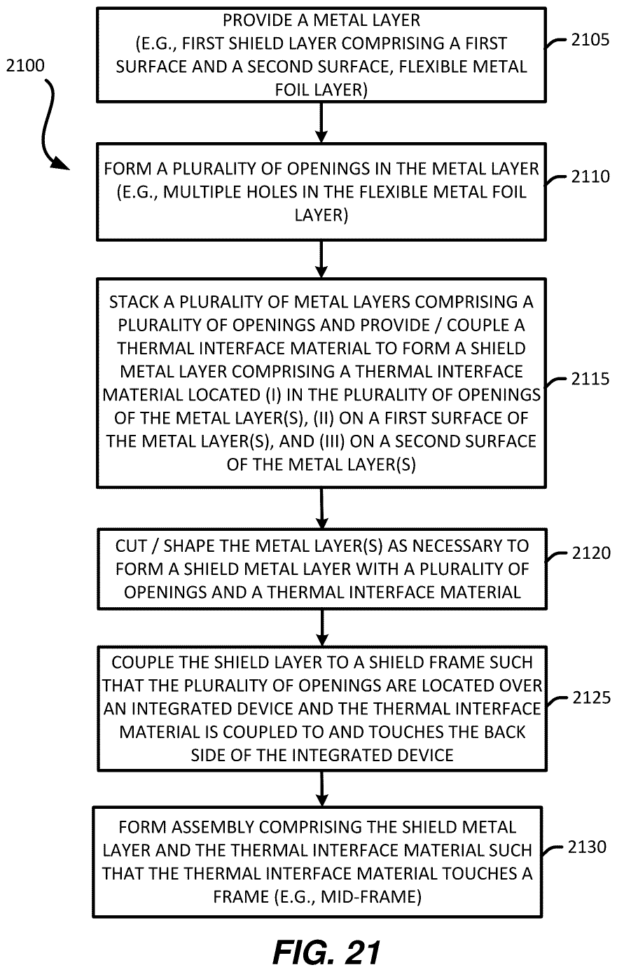

FIG. 21 illustrates an exemplary flow diagram of a method 2100 for providing an assembly comprising an integrated device, a shield metal layer with openings and a thermal interface. In some implementations, the method 2100 of FIG. 21 may be used to fabricate the assembly 300. However, the method 2100 may be used to fabricate any of the assembly described in the disclosure and/or any of the shield layer described in the disclosure.

It should be noted that the method 2100 of FIG. 21 may combine one or more processes in order to simplify and/or clarify the method for fabricating a thermally conductive layers. In some implementations, the order of the processes may be changed or modified.

The method provides (at 2105) a metal layer. Stage 1 of FIG. 18, illustrates and describes an example of a metal layer 1808a that is provided. The metal layer 1808a may have different shapes. Different implementations may use different materials for the metal layer 1808a. In some implementations, providing a metal layer may include providing a flexible metal foil layer. In some implementations, providing a metal layer may include providing a first shield layer comprising a first surface and a second surface.

The method forms (at 2110) a plurality of openings in the metal layer. Stage 2 of FIG. 18, illustrates and describes an example of a plurality of openings 1880a that are formed in in the metal layer 1808a. A laser drilling process may be used to form the plurality of openings 1880a. However, different implementations may use different processes for forming the plurality of openings 1880a. The plurality of openings 1880a may have different number of openings. Each opening may have the same or similar sizes and/or shapes. However, in some implementations, one or more openings may have different sizes and/or shapes. The plurality of openings 1880a may be have different arrangements such as different array sizes.

The method forms (at 2115) a stack of metal layers with a plurality of openings. Stage 3 of FIG. 18, illustrates and describes an example of a plurality of metal layers 1808 that are provided, where each metal layer includes a plurality of openings. In this example, the plurality of metal layers 1808 includes a metal layer 1808a, a metal layer 1808b, a metal layer 1808c, a metal layer 1808d, a metal layer 1808e and a metal layer 1808f. The metal layers of the plurality of metal layers 1808 may all be the same material or may include different material. For example, a first metal layer may include a first material, a second metal layer may include a second material and a third metal layer may include a third material.

The method also provides and/or couples (at 2115) a thermal interface material to the stacked metal layer. Stage 4 of FIG. 18, illustrates and describes a thermal interface material 1810 that is provided and coupled to the plurality of metal layers 1808. The thermal interface material may be provided in the plurality of openings of the plurality of metal layers 1808. The plurality of metal layers 1808 and the thermal interface material 1810 may be pressed and/or compressed. Different implementations may use different materials for the thermal interface material 1810.

The method cuts and/or shapes (at 2120) the metal layers to form a shield metal layer with openings and a thermal interface material. Stages 5 and 6 of FIG. 18, illustrate and describe how the metal layer(s) can be cut to form a shield metal layer. Stage 4 of FIG. 19 and Stage 4 of FIG. 20, also illustrate and describe how the metal layer(s) can be cut to form a shield metal layer.

Once the shield metal layer(s) has been provided and/or fabricated, the method couples (at 2125) the shield layer to a shield frame (e.g., 306), such that a plurality of openings are located over an integrated device, and the thermal interface material is coupled to the integrated device. The method may thus couple (at 2125) the shield metal layer and the thermal interface material to an integrated device such that the thermal interface material is coupled to the integrated device. The thermal interface material may be coupled to a back side of the integrated device. The integrated device and the shield frame may be coupled to a board (e.g., printed circuit board).

The method forms (at 2130) an assembly that includes an integrated device, the shield metal layer, the thermal interface material and a frame. As an example, the thermal interface material may be coupled to and touching the integrated device and the frame (e.g., mid-frame). The frame may include a heat sink and/or a heat pipe. Thus, the thermal interface material may be coupled to a heat sink and/or a heat pipe.

### Exemplary Electronic Devices

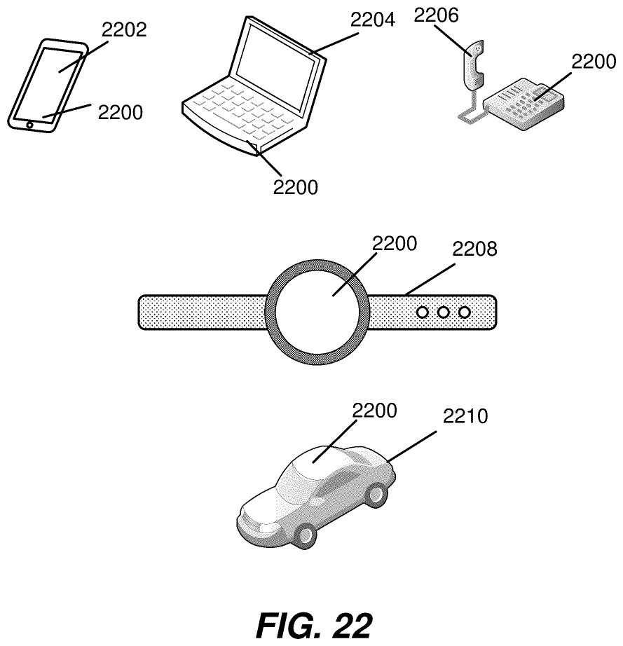

FIG. 22 illustrates various electronic devices that may be integrated with any of the aforementioned device, integrated device, integrated circuit (IC) package, integrated circuit (IC) device, semiconductor device, integrated circuit, die, interposer, package, package-on-package (PoP), System in Package (SiP), or System on Chip (SoC). For example, a mobile phone device 2202, a laptop computer device 2204, a fixed location terminal device 2206, a wearable device 2208, or automotive vehicle 2210 may include a device 2200 as described herein. The device 2200 may be, for example, any of the devices and/or integrated circuit (IC) packages described herein. The devices 2202, 2204, 2206 and 2208 and the vehicle 2210 illustrated in FIG. 22 are merely exemplary. Other electronic devices may also feature the device 2200 including, but not limited to, a group of devices (e.g., electronic devices) that includes mobile devices, hand-held personal communication systems (PCS) units, portable data units such as personal digital assistants, global positioning system (GPS) enabled devices, navigation devices, set top boxes, music players, video players, entertainment units, fixed location data units such as meter reading equipment, communications devices, smartphones, tablet computers, computers, wearable devices (e.g., watches, glasses), Internet of things (IOT) devices, servers, routers, electronic devices implemented in automotive vehicles (e.g., autonomous vehicles), or any other device that stores or retrieves data or computer instructions, or any combination thereof.

One or more of the components, processes, features, and/or functions illustrated in FIGS. 1-8, 12-14 and/or 18-22 may be rearranged and/or combined into a single component, process, feature or function or embodied in several components, processes, or functions. Additional elements, components, processes, and/or functions may also be added without departing from the disclosure. It should also be noted FIGS. 1-8, 12-14 and/or 18-22 and its corresponding description in the present disclosure is not limited to dies and/or ICs. In some implementations, FIGS. 1-8, 12-14 and/or 18-22 and its corresponding description may be used to manufacture, create, provide, and/or produce devices and/or integrated devices. In some implementations, a device may include a die, an integrated device, an integrated passive device (IPD), a die package, an integrated circuit (IC) device, a device package, an integrated circuit (IC) package, a wafer, a semiconductor device, a package-on-package (POP) device, a heat dissipating device and/or an interposer.

It is noted that the figures in the disclosure may represent actual representations and/or conceptual representations of various parts, components, objects, devices, packages, integrated devices, integrated circuits, and/or transistors. In some instances, the figures may not be to scale. In some instances, for purpose of clarity, not all components and/or parts may be shown. In some instances, the position, the location, the sizes, and/or the shapes of various parts and/or components in the figures may be exemplary. In some implementations, various components and/or parts in the figures may be optional.

The word “exemplary” is used herein to mean “serving as an example, instance, or illustration.” Any implementation or aspect described herein as “exemplary” is not necessarily to be construed as preferred or advantageous over other aspects of the disclosure. Likewise, the term “aspects” does not require that all aspects of the disclosure include the discussed feature, advantage or mode of operation. The term “coupled” is used herein to refer to the direct or indirect coupling (e.g., mechanical coupling) between two objects. For example, if object A physically touches object B, and object B touches object C, then objects A and C may still be considered coupled to one another-even if they do not directly physically touch each other. The term “electrically coupled” may mean that two objects are directly or indirectly coupled together such that an electrical current (e.g., signal, power, ground) may travel between the two objects. Two objects that are electrically coupled may or may not have an electrical current traveling between the two objects. Electromagnetic coupling may mean that a signal from one circuit and/or component affects a signal of another circuit and/or component. Electromagnetic coupling may cause crosstalk. Electromagnetic coupling may be a form of signal coupling. The use of the terms “first”, “second”, “third” and “fourth” (and/or anything above fourth) is arbitrary. Any of the components described may be the first component, the second component, the third component or the fourth component. For example, a component that is referred to a second component, may be the first component, the second component, the third component or the fourth component. The terms “top” and “bottom” are arbitrary. A component that is located on top may be located over a component that is located on a bottom. A top component may be considered a bottom component, and vice versa. As described in the disclosure, a first component that is located “over” a second component may mean that the first component is located above or below the second component, depending on how a bottom or top is arbitrarily defined. In another example, a first component may be located over (e.g., above) a first surface of the second component, and a third component may be located over (e.g., below) a second surface of the second component, where the second surface is opposite to the first surface. It is further noted that the term “over” as used in the present application in the context of one component located over another component, may be used to mean a component that is on another component and/or in another component (e.g., on a surface of a component or embedded in a component). Thus, for example, a first component that is over the second component may mean that (1) the first component is over the second component, but not directly touching the second component, (2) the first component is on (e.g., on a surface of) the second component, and/or (3) the first component is in (e.g., embedded in) the second component. The term “encapsulating” means that the object may partially encapsulate or completely encapsulate another object. The term “surrounding” means that an object(s) may partially surround or completely surround another object. The term “extends through” means that the object may partially extend or completely extend through another object. It is further noted that the term “over” as used in the present application in the context of one component located over another component, may be used to mean a component that is on another component and/or in another component (e.g., on a surface of a component or embedded in a component). Thus, for example, a first component that is over the second component may mean that (1) the first component is over the second component, but not directly touching the second component, (2) the first component is on (e.g., on a surface of) the second component, and/or (3) the first component is in (e.g., embedded in) the second component. A first component that is located “in” a second component may be partially located in the second component or completely located in the second component. The term “about ‘value X’”, or “approximately value X”, as used in the disclosure means within 10 percent of the ‘value X’. For example, a value of about 1 or approximately 1, would mean a value in a range of 0.9-1.1. A “plurality” of components may include all the possible components or only some of the components from all of the possible components. For example, if a device includes ten components, the use of the term “the plurality of components” may refer to all ten components or only some of the components from the ten components.

In some implementations, an interconnect is an element or component of a device or package that allows or facilitates an electrical connection between two points, elements and/or components. In some implementations, an interconnect may include a trace, a via, a pad, a pillar, a redistribution metal layer, and/or an under bump metallization (UBM) layer. An interconnect may include one or more metal components (e.g., seed layer+metal layer). In some implementations, an interconnect may include an electrically conductive material that may be configured to provide an electrical path for a signal (e.g., a data signal), ground and/or power. An interconnect may be part of a circuit. An interconnect may include more than one element or component. An interconnect may be defined by one or more interconnects. Different implementations may use different processes and/or sequences for forming the interconnects. In some implementations, a chemical vapor deposition (CVD) process, a physical vapor deposition (PVD) process, a sputtering process, a spray coating, and/or a plating process may be used to form the interconnects.

Also, it is noted that various disclosures contained herein may be described as a process that is depicted as a flowchart, a flow diagram, a structure diagram, or a block diagram. Although a flowchart may describe the operations as a sequential process, many of the operations can be performed in parallel or concurrently. In addition, the order of the operations may be re-arranged. A process is terminated when its operations are completed.

In the following, further examples are described to facilitate the understanding of the disclosure.

Aspect 1: A device comprising a board; an integrated device coupled to the board; a shield frame coupled to the board; a shield layer coupled to the shield frame, wherein the shield layer comprises a first surface, a second surface and a plurality of openings; and a thermal interface material coupled to (i) the integrated device and (ii) the shield layer. The thermal interface material is located in the plurality of openings of the shield layer. The thermal interface material touches the integrated device, the first surface of the shield layer and the second surface of the shield layer.

Aspect 2: The device of aspect 1, further comprising a frame, wherein the thermal interface material is coupled to and touching the frame.

Aspect 3: The device of aspects 1 through 2, wherein the plurality of openings are located over the integrated device.

Aspect 4: The device of aspects 1 through 3, wherein each opening of the plurality of openings has a width that is about 2 millimeters or less.

Aspect 5: The device of aspects 1 through 4, wherein the plurality of openings comprise a first opening that has a first width, and wherein the plurality of openings comprise a second opening that has a second width.

Aspect 6: The device of aspects 1 through 5, wherein the plurality of openings comprise a first opening that has a first shape, and wherein the plurality of openings comprise a second opening that has a second shape.

Aspect 7: The device of aspects 1 through 6, wherein the plurality of openings are arranged in rows and/or columns of openings.

Aspect 8: The device of aspects 1 through 7, wherein the thermal interface material includes a thermal grease, a thermal gel, a thermal putty, a thermal pad, and/or thermal tape.

Aspect 9: The device of aspects 1 through 8, wherein the shield layer is configured as an electromagnetic interference (EMI) shield.

Aspect 10: The device of aspects 1 through 9, wherein the shield layer includes a plurality of laminated metal layers.

Aspect 11: The device of aspects 1 through 10, wherein the shield layer includes a first metal layer and a second metal layer, wherein the first metal layer includes a first material, and wherein the second metal layer includes a second material that is different from the first material.

Aspect 12: The device of aspects 1 through 11, wherein the shield layer includes a plurality of metal foils.

Aspect 13: The device of aspects 1 through 12, wherein the shield layer is coupled to the shield frame through an adhesive.

Aspect 14: The device of aspects 1 through 13, wherein the thermal interface material includes a first material and a second material, wherein the first material of the thermal interface material touches the first surface of the shield layer, and wherein the second material of the thermal interface material touches the second surface of the shield layer.

Aspect 15: The device of aspects 1 through 14, further comprising a second integrated device coupled to the board; and a second thermal interface material coupled to the second integrated device and the shield layer. The shield layer further comprises a second plurality of openings located over the second integrated device. The second thermal interface material is located in the second plurality of openings of the shield layer. The second thermal interface material touches the second integrated device, the first surface of the layer and the second surface of the shield layer.

Aspect 16: The device of aspect 15, further comprising a frame, wherein the thermal interface material and the second thermal interface material are coupled to and touching the frame.

Aspect 17: The device of aspects 1 through 14, further comprising a second integrated device coupled to the board; a second shield layer comprising a first surface, a second surface, and a second plurality of openings located over the second integrated device; and a second thermal interface material coupled to the second integrated device and the second shield layer. The second thermal interface material is located in the second plurality of openings of the second shield layer. The second thermal interface material touches the second integrated device, the first surface of the second shield layer and the second surface of the shield layer.

Aspect 18: The device of aspects 15 through 17, wherein the first integrated device includes a first chiplet fabricated using a first technology node, and wherein the second integrated device includes a second chiplet fabricated using a second technology node.

Aspect 19: The device of aspects 1 through 18, wherein the device selected from a group consisting of a music player, a video player, an entertainment unit, a navigation device, a communications device, a mobile device, a mobile phone, a smartphone, a personal digital assistant, a fixed location terminal, a tablet computer, a computer, a wearable device, a laptop computer, a server, an internet of things (IOT) device, and a device in an automotive vehicle.

Aspect 20: A method that provides a first shield layer comprising a first surface and a second surface. The method forms a first plurality of openings in the first shield layer. The method couples a first thermal interface material to the first shield layer such that the first thermal interface material is located in the first plurality of openings of the first shield layer touching (i) the first surface of the first shield layer and (ii) the second surface of the first shield layer. The method couples the first shield layer to a shield frame, such that the first plurality of openings are located over an integrated device, and wherein the first thermal interface material is coupled to the integrated device.

Aspect 21: The method of aspect 20, further comprising providing a second shield layer comprising a first surface and a second surface; forming a second plurality of openings in the second shield layer; and coupling a second thermal interface material to the second shield layer such that the second thermal interface material is located in the second plurality of openings of the second shield layer and touching (i) the first surface of the second shield layer and (ii) the second surface of the second shield layer.

Aspect 22: The method of aspect 21, further comprising coupling (i) the second shield layer and the second thermal interface material to (ii) the first shield layer and the first thermal interface material, to form a shield layer.

Aspect 23: The method of aspects 21 through 22, wherein the first shield layer includes a different material from the second shield layer.

Aspect 24: The method of aspects 21 through 23, wherein the first thermal interface material includes a different material from the second thermal interface material.

Aspect 25: The method of aspects 20 through 24, further comprising providing a frame such that the first thermal interface material is touching the frame.

Aspect 26: A method that provides a first shield layer comprising a first surface and a second surface. The first shield layer includes a first plurality of openings. A first thermal interface material is coupled to the first shield layer such that the first thermal interface material is located in the first plurality of openings of the first shield layer touching (i) the first surface of the first shield layer and (ii) the second surface of the first shield layer. The first shield layer may form a shield layer. The method couples the first shield layer to a shield frame, such that the first plurality of openings are located over an integrated device, and wherein the first thermal interface material is coupled to the integrated device.

Aspect 27: The method of aspect 26, further comprising providing a frame such that the first thermal interface material is touching the frame.

Aspect 28: The method of aspects 26 through 27, wherein the shield frame is coupled to a first surface of a board, and wherein the integrated device is coupled to the first surface of the board.

The various features of the disclosure described herein can be implemented in different systems without departing from the disclosure. It should be noted that the foregoing aspects of the disclosure are merely examples and are not to be construed as limiting the disclosure. The description of the aspects of the present disclosure is intended to be illustrative, and not to limit the scope of the claims. As such, the present teachings can be readily applied to other types of apparatuses and many alternatives, modifications, and variations will be apparent to those skilled in the art.

1. A device comprising:
a board;
an integrated device coupled to the board;
a shield frame coupled to the board;
a shield layer coupled to the shield frame, wherein the shield layer comprises a first surface, a second surface and a plurality of openings; and
a thermal interface material coupled to (i) the integrated device and (ii) the shield layer, wherein the thermal interface material is located in the plurality of openings of the shield layer, and
wherein the thermal interface material touches the integrated device, the first surface of the shield layer and the second surface of the shield layer.

2. The device of claim 1, further comprising a frame, wherein the thermal interface material is coupled to and touching the frame.

3. The device of claim 1, wherein the plurality of openings are located over the integrated device.

4. The device of claim 1, wherein each opening of the plurality of openings has a width that is about 2 millimeters or less.

5-6. (canceled)

7. The device of claim 1, wherein the plurality of openings are arranged in rows and/or columns of openings.

8. (canceled)

9. The device of claim 1, wherein the shield layer is configured as an electromagnetic interference (EMI) shield.

10. The device of claim 1, wherein the shield layer includes a plurality of laminated metal layers.

11. The device of claim 1,
wherein the shield layer includes a first metal layer and a second metal layer, wherein the first metal layer includes a first material, and
wherein the second metal layer includes a second material that is different from the first material.

12. The device of claim 1, wherein the shield layer includes a plurality of metal foils.

13. The device of claim 1, wherein the shield layer is coupled to the shield frame through an adhesive.

14. The device of claim 1,
wherein the thermal interface material includes a first material and a second material,
wherein the first material of the thermal interface material touches the first surface of the shield layer, and
wherein the second material of the thermal interface material touches the second surface of the shield layer.

15. The device of claim 1, further comprising:
a second integrated device coupled to the board; and
a second thermal interface material coupled to the second integrated device and the shield layer, and
wherein the shield layer further comprises a second plurality of openings located over the second integrated device,
wherein the second thermal interface material is located in the second plurality of openings of the shield layer, and
wherein the second thermal interface material touches the second integrated device, the first surface of the layer and the second surface of the shield layer.

16. The device of claim 15, further comprising a frame, wherein the thermal interface material and the second thermal interface material are coupled to and touching the frame.

17. The device of claim 1, further comprising:
a second integrated device coupled to the board;
a second shield layer comprising a first surface, a second surface, and a second plurality of openings located over the second integrated device; and
a second thermal interface material coupled to the second integrated device and the second shield layer, and
wherein the second thermal interface material is located in the second plurality of openings of the second shield layer, and
wherein the second thermal interface material touches the second integrated device, the first surface of the second shield layer and the second surface of the shield layer.

18. The device of claim 17,
wherein the first integrated device includes a first chiplet fabricated using a first technology node, and
wherein the second integrated device includes a second chiplet fabricated using a second technology node.

19. The device of claim 1, wherein the device selected from a group consisting of a music player, a video player, an entertainment unit, a navigation device, a communications device, a mobile device, a mobile phone, a smartphone, a personal digital assistant, a fixed location terminal, a tablet computer, a computer, a wearable device, a laptop computer, a server, an internet of things (IoT) device, and a device in an automotive vehicle.

20. A method comprising:
providing a first shield layer comprising a first surface and a second surface;
forming a first plurality of openings in the first shield layer;
coupling a first thermal interface material to the first shield layer such that the first thermal interface material is located in the first plurality of openings of the first shield layer touching (i) the first surface of the first shield layer and (ii) the second surface of the first shield layer; and
coupling the first shield layer to a shield frame, such that the first plurality of openings are located over an integrated device, and wherein the first thermal interface material is coupled to the integrated device.

21. The method of claim 20, further comprising:
providing a second shield layer comprising a first surface and a second surface;
forming a second plurality of openings in the second shield layer; and
coupling a second thermal interface material to the second shield layer such that the second thermal interface material is located in the second plurality of openings of the second shield layer and touching (i) the first surface of the second shield layer and (ii) the second surface of the second shield layer.

22. The method of claim 21, further comprising:
coupling (i) the second shield layer and the second thermal interface material to (ii) the first shield layer and the first thermal interface material, to form a shield layer.

23-24. (canceled)

25. The method of claim 20, further comprising providing a frame such that the first thermal interface material is touching the frame.
